(19) United States
(12) Patent Application Publication
(10) Pub. No.: US 2017/0240473 A1
(43) Pub. Date: Aug. 24, 2017

(54) MESOPOROUS MATERIALS FROM NANOPARTICLE ENHANCED POLYSACCHARIDES

(71) Applicants: UNIVERSITY OF YORK, North Yorkshire (GB); CONSEJO SUPERIOR DE INVESTIGACIONES CIENTIFICAS, Madrid (ES)

(72) Inventors: Vitaly BUDARIN, North Yorkshire (GB); James Hanley CLARK, North Yorkshire (GB); Gary James ELLIS, Madrid (ES); Peter Samuel SHUTTLEWORTH, Madrid (ES); Horacio Javier SALAVAGIONE, Madrid (ES)

(21) Appl. No.: 15/511,353

(22) PCT Filed: Sep. 15, 2015
(86) PCT No.: PCT/GB2015/052676

§ 371 Date: Mar. 15, 2017

(30) Foreign Application Priority Data
Sep. 15, 2014 (GB) 1416239.0

(51) Int. Cl. C04B 35/78; C04B 38/00; H01M 4/583; C08L 3/02; H01G 11/36; H05K 9/00; C04B 35/624; C04B 35/626

(52) U.S. Cl. CPC C04B 35/78; C04B 35/624; C04B 38/0045; C04B 35/6261; C04B 38/0067; C01B 31/02; C08L 3/02; H01G 11/36; H05K 9/0073; H01M 4/583; C04B 2235/422; C04B 2235/48; C04B 2235/667; C04B 2235/77; C04B 2235/96; C04B 2235/9607; C01P 2002/82

(57) ABSTRACT

There is described a mesoporous composite material comprising carbon nanoparticles dispersed in a mesoporous carbonaceous material.

### FIELD OF THE INVENTION

The present invention relates to mesoporous carbonaceous composite materials derived from native polysaccharides incorporating carbon-based nanoparticles, a method of preparing the same, and more particularly shaped composite materials where the nanoparticles (including but not exclusively graphene, graphene oxide, graphite, carbon nanotubes and fullerene etc.) are distributed within a carbonaceous mesoporous network, having superior electrical and/or thermal conductivity, electromagnetic adsorption, tailored surface-specific functionality as well as improved gas and liquid flow characteristics and capacitance with scan rate, and cyclability stability.

### BACKGROUND OF THE INVENTION

Almost 1 million tonnes per annum of porous carbons are used in a variety of applications, including water treatment, gas purification, decolourisation and absorbency. Porous materials are understood as a solid matrix composed of an interconnected network of voids filled with a liquid or gas; typical examples of porous carbon materials include activated carbon and charcoal. The properties of these carbon materials can be controlled by two major characteristics such as pore size and functionality.

With respect to carbon porosity, the International Union of Pure and Applied Chemistry (IUPAC) has defined three classes of pore: micropore (pore size <2 nm), mesopore (2 nm<pore size <50 nm) and macropore (pore size >50 nm). Herein, mesoporous materials are understood as materials containing a significant volume of mesopore (more than 66 vol. %) and a total pore volume higher than 0.3 ml/g.

Mesoporous carbons have massive advantages in applications where the diffusion of species within the pore network is essential, such as catalysis, separation and the adsorption of large molecules (e.g. proteins, enzymes and humine). A number of methods exist to promote mesoporosity in carbon materials. These include templating (for example, ^{1, 2}), activation (for example,³) and direct carbonisation of polymer blends that include a carbonisable polymer (for example,⁴). However, all the aforementioned methods involve highly aggressive chemicals, are expensive due to multiple stages and/or high temperature treatment, and are poorly scalable.

With respect to carbon functionality, mesoporous carbons are produced by a carbonisation (pyrolysis) process from a large variety of carbon-containing source materials (carbonisation being the conversion of an organic substance into carbon or a carbon-containing residue in absence of oxygen). The functionality of the obtained carbon materials, and therefore the adsorptive power of the ultimate product, depend among other factors on the nature of the source material, and on the preparative methods employed, especially the temperature of carbonisation.

Polysaccharides are any class of carbohydrate polymer composed of a chain of monosaccharide repeat units linked together by glycosidic bonds, and include heteropolysaccharides where the monosaccharide repeat units are different and homopolysaccharides where the monosaccharide repeat units are the same. Natural polysaccharides include cellulose, chitin, xylans, arabinoxylans, pectins, alginates, starch (a carbohydrate normally consisting of the two polymers amylose and amylopectin), glycogen, laminarin, chrysolaminarin, mannan, fucoidan and galactomannan, but are not limited to these, and can be obtained from biomass. Herein, polysaccharides are understood as natural materials of polymeric nature (fundamental to the invention). Depolymerisation or hydrolysis to produce oligosaccharides or sugars is not a relevant procedure for this invention.

All biomass-derived polysaccharide feedstocks contain a significant amount of oxygen. During the carbonisation of polysaccharides, the oxygen content within the matter is reduced and the carbon-to-oxygen ratio is increased [5]. Herein, carbon rich (carbon content >45 wt. %) materials produced from biomass at elevated temperature are understood as carbonaceous materials.

The carbon-to-oxygen index (C:O) is a fundamental factor in mesoporous carbonaceous systems produced from biomass (see [P 1]). A number of very promising applications of mesoporous carbons such as process electrode materials for batteries, fuel cells, and supercapacitors as well as organic molecules separation and catalysis require carbon materials with special graphite-like functionality (high C:O index) that provide large areas of delocalised electrons and are characterised by high electrical conductivity, mechanical and chemical stability. To achieve this critical C:O index using standard methods of carbonisation, very high temperatures of preparation (above 1000° C.) are required. As a consequence significant mass loss occurs during the carbonisation process, special high-temperature equipment is required and the energy consumption for the process is excessively high.

Typically, activated and mesoporous carbons are produced as a powder or particles. This reduces their potential electrical and thermal-conductivity, reduces chromatographic resolution, and limits both catalytic and electrochemical applications. A continuous porous network within a carbonaceous monolithic structure is desirable and can significantly improve the above mentioned characteristics. Herein, mesoporous monolithic materials are understood as materials that present shape and dimensional stability and contain continuous uniform meso-/macro-pore passages that allow fluid/gas flow-through.

The incorporation of carbon-based nanoparticles into a polymeric matrix can improve and diversify the properties of the matrix material, including mechanical, thermal, electrical, barrier, amongst others. Three-dimensional (3D), two-dimensional (2D), one-dimensional (1D) and zero dimensional (0D) carbon nanofiller materials include graphite (3D), graphene and its derivatives (2D), carbon nanotubes (1D), and fullerenes (0D).

Graphite (Gr) comprises a 3D structure based on sheets of carbon atoms spaced 0.142 nm apart organised in a honeycomb matrix, with an inter-sheet spacing of 0.355 nm. Graphite is a typically employed filler for polymer matrices, including polysaccharides, and is used to enhanced mechanical strength, tribological behaviour, thermal stability and fire retardancy, thermal and electrical conductivity, amongst others, although in all cases relatively high quantities (>20%) are required to obtain significant improvements (see for example, [P2]).

Graphite is soft and under mechanical treatment few-layer or monolayer (2D nanoparticles) of graphite can be produced, often denominated graphene nanoplatelets (GNP), which can also be produced by other non-oxidising and mechanical methods. Another example is expanded graphite in which graphitic layers are disrupted to make a porous structure. This type of material is very important in ammonia synthesis. However, although layers are easy to separate they are difficult to keep apart and hence, the method of making expanded graphite is expensive and not environmentally friendly.

Graphene (G) is a 2D material comprising a monolayer of carbon atoms in a honeycomb structure and is equivalent to a single graphite layer. Since it's fortuitous isolation reported by Novoselov, et al. in 2004 [6] graphene has become probably the most promising carbon nanomaterial due to its unique properties, including mechanical modulus (>1 TPa) and strength (>130 GPa), high surface area (>2500 m²g⁻¹) thermal conductivity (˜4000 Wm⁻¹K⁻¹) and electrical conductivity (˜6000 Scm⁻¹), transparency, barrier properties, etc., and it is the lightest (1 m²=0.7 mg), thinnest and less dense material available. In this respect, its incorporation into polymer matrices has become an area of considerable activity. However, due to the difficulty in mass producing pristine graphene, in most applications where quantity is required it is typically produced by the modified Hummers method that comprises strong acid-induced oxidation and subsequent delamination of graphite, to produce graphene oxide (GO), a highly defective material rich in oxygenated species. Thermal or chemical reduction of GO produces reduced graphene oxide (rGO), a less defective material where the oxygenated species have been removed. Other methods that produce higher quality graphene, but in smaller quantities include chemical vapour deposition (CVD), mechanical exfoliation and electrochemical methods (see for example [7]). Herein, and for the purpose of the invention, Graphene refers to all graphene-like materials including, but not exclusively, GO, rGO, GNP, graphene intercalation compounds (GIC), etc. independent of their origin or production method, and also includes functionalised graphene materials (denominated f-G), where the functionalisation includes incorporation of different chemical groups on the edge and/or basal planes of the graphene sheets.

Carbon nanotubes (CNT), in contrast to graphene-like materials, are 1D materials that can be effectively understood as graphene sheets rolled-up into tubes whose walls are one carbon atom thick, and whose lengths fall in the range of tens of nanometers to various microns. Single-walled carbon nanotubes (SWCNT) have a unique tube, double-walled carbon nanotubes (DWCNT) comprise two concentric tubes, and multi-walled carbon nanotubes (MWCNT) comprise three or more concentric tubes. The incorporation of CNT into polymeric matrices is well known and documented in the literature. Herein, for the purpose of the invention, CNT will refer to all types of carbon nanotubes, independent of their structure or aspect ratio, and includes sidewall and/or end functionalised CNTs (denominated f-CNT).

A major limitation to property improvement with nanoparticle fillers is the poor dispersion of the nanoparticles within the matrix, due to their inherent inertness and their high tendency to agglomerate or self-associate through strong van der Waals forces. Several strategies can be employed to improve this, and their effectiveness depends on the nature of both the nanoparticle and the matrix employed (see for example [8]). Mechanical methods, including solid-state mixing, temperature mediated or molten mixing when the matrix can flow or be melted under the effect of temperature, shear-mixing, ball-milling or impact-milling (at room temperature or under cryogenic conditions), and ultrasound treatments can all be used. However, these only have moderate success and often induce defects or damage to the nanoparticles, such as tube shortening through breakage in the case of CNT, or flake fracture in the case of graphene. Wrapping of the nanoparticles with a compatibilising material is another strategy that has been employed, as have grafting-to or grafting-from nanoparticle surfaces of polymer chains. One of the main objectives of research efforts has been to find an adequate balance between processing methods and dispersion as a function of the polymer type and nature in order to optimise material properties.

Graphene and graphene-like materials have been incorporated into polysaccharides. For example, nanocomposite films of polysaccharide matrices (chitosan-starch, and carboxymethylcellulose-starch) reinforced with graphene or graphene oxide can show 3-fold improvements in modulus (for example, [9]), especially when strong interactions between the filler and matrix are generated. In another example, by very long (10 hours) ultrasonic dispersion of graphite oxide in starch hydrolyates (final mixture of sugars, oligomers and other dextrin like products) and then hydrothermal processing followed by carbonisation in a very large excess of phosphoric acid, graphene/carbon microsphere composites can be obtained with improved capacitance properties [P3]. In another example, with potential applications in battery materials, graphene coated microspheres have been described [P4]. Whilst interesting properties have been shown in the aforementioned works, the materials described are not mesoporous, have no access to tuneable functionality, are not monolithic and their conductivity is unknown.

### Problem to be Solved by the Invention

Existing technology is lacking materials with high levels of mesoporosity combined with controllable surface functionalisation, and with the ability to be shaped into designed forms. In current methodologies a large mass loss takes place during carbonisation in order to achieve materials with high carbon:oxygen (C:O) ratios. Further, from an industrial viewpoint there is a need for materials in monolithic form that combine high levels of mesopore and low carbon content, i.e. high functionality and tailored absorption chemistries, along with superior physicochemical properties, including electrical and/or thermal conductivity, and good mechanical integrity.

### SUMMARY OF THE INVENTION

The object of the invention is the formation of a novel class of monolithic mesoporous carbonaceous—carbon nanoparticle composites with tuneable functionality based on the ability of naturally-derived biopolymers to enhance the dispersion and organisation of carbon-based nanoparticles within a mesoporous network in such a manner as to significantly augment the materials mechanical, adsorption and electrical and/or thermal conductivity properties, etc. and simultaneously modify the porous surface properties to equal or improve those of competitor materials produced at much higher temperatures. The nanocomposites obtained after carbonisation demonstrate variety of tuneable properties such as superior and/or tuneable electrical conductivity, adsorption, and surface-specific functionality and mechanical reinforcement, that vary as a function of the nanoparticle type and concentration and the processing method and conditions employed. Potential applications for these materials lie predominately, but not exclusively, in the areas of catalysis, filtration, adsorption/absorption, membrane technology, chromatography, supercapacitors, desalination membranes and solar collectors amongst others.

Solar collectors convert solar irradiation energy into thermal energy that can then be used for water heating applications etc.⁵ Additionally, the special nature of the materials can also open new avenues for green methods for nanoparticle dispersion, optical sensors and electromagnetic absorption, amongst others.

Therefore, according to a first aspect of the invention there is provided a mesoporous composite material comprising carbon nanoparticles dispersed in a mesoporous carbonaceous material.

In this aspect of the invention the carbon nanoparticles are substantially homogenously dispersed in the mesoporous carbonaceous material.

The carbon nanoparticles may be based on one or more of graphene, graphene oxide, graphite and carbon nanotubes.

The mesoporous carbonaceous material may be derived from one or more mesoporous polysaccharides, for example, the mesoporous carbonaceous material may be produced by the carbonisation of one or more mesoporous polysaccharides. The mesoporous composite material precursor may be in the form of a stable organic gel, before the carbonisation step.

It will be understood by the person skilled in the art that the carbon-to-oxygen ratio may be tuneable.

The mesoporous composite material of the present invention may be shaped in different forms, e.g. the material may comprise a monolith. Such a monolith structure may comprise a tuneable microporous or mesoporous structure throughout. The mesoporous composite material may comprise a tailored pore distribution.

The mesoporous composite material may have improved electrical conductivity and/or improved thermal conductivity when compared to prior art materials, e.g. non-porous materials.

In addition, the mesoporous composite material may have improved absorption in the electromagnetic spectrum.

Extra functionality, for example, via specific functionalisation on the nanoparticle surface, may be incorporated into the mesoporous composite material of the invention. For example, the mesoporous composite material of the invention may incorporate extra functionality via temperature mediated carbonisation of the polysaccharide or the polysaccharide/nanoparticle hybrid. In addition, the mesoporous composite material may possess controllable macroporosity (density).

According to a further aspect of the invention there is provided a method of preparing a mesoporous composite material comprising carbon nanoparticles dispersed in a mesoporous carbonaceous material as herein described, said method comprising dispersion of the carbon nanoparticles in a molten carbonaceous material.

According to this aspect of the invention the mesoporous carbonaceous material may be prepared by solvent exchange and drying of the carbonaceous material.

### DETAILED DESCRIPTION OF THE INVENTION

Stable mesoporous carbonaceous materials can be produced by direct carbonisation of mesoporous polysaccharides at low to mid-range temperatures [P 1], however very high temperature (higher than 1500° C.) has to be applied to achieve C:O indices, electrical conductivity and mechanical performance that are typical for carbons used in chromatography and electrochemistry [1, P5], which lead to high energy consumption and significant sample mass loss and as a result substantially increasing final cost of the mesoporous product. Furthermore, materials produced at temperature below 800° C. lack significant conjugated aromatic functional groups that restrict applications of these materials in areas dependent on π-π interaction such as catalysis, adsorption, industrial water purification, etc. On the other hand, carbon nanoparticles generally have well-ordered structures with very high carbon contents, >90% for graphene and carbon nanotubes, or can be easily transformed to pure carbon in the case of graphene derivatives (GO, etc.). In order to overcome the aforementioned disadvantages of mesoporous carbonaceous materials, composite mesoporous materials based on bioderived polysaccharides that incorporate carbon nanoparticles have been developed that can unite the physicochemical characteristics of those carbon materials conventionally obtained at much higher temperatures, and incorporate improved electrical conductivity and mechanical performance, or provide a range of improvements to materials with high functionality prepared at lower temperatures.

The underlining strategy in the invention is the maximisation of the influence of the carbon nanoparticles on the produced materials through their effective dispersion within the polysaccharide chains in the gel state, and the synergistic relationship between the polysaccharide and the nanoparticles that has a strong influence on all stages of the material production, from initial gel network to the final carbonised mesoporous product. It is important to highlight that this effect works with polymers (i.e. polysaccharide), and cannot be achieved with simple monomers or oligomer sugars, etc. As a consequence, using the methodologies described, only a small amount of the molecular dispersed nanoparticles is required to dramatically modify the properties of biomass-derived carbonaceous materials. Utilisation of both the mesoporous properties of the polysaccharides, and their extraordinary mobility at gelation and through the molten carbonaceous stage, are key innovative strategies for the dispersion of carbon nanoparticles within mesoporous carbonaceous network that are proposed here.

The invention provides a method for preparing different carbonaceous nanocomposites described in detail here, and is comprised of the following 6 stages:
a) Stage 1: Ball milling of a carbohydrate-carbon nanoparticles mixture for times between 0-3 h.
b) Stage 2: Either (i) Microwave-assisted gelation of the obtained mixture undertaken at temperatures between 50-180° C., accompanied with sonication conditions (0-1 hour etc.) steps, or (ii) similar carried out under convection heating.
c) Stage 3: Gel retrogradation at temperatures from between −10° C. to approx. 5° C. below the gelatinisation point, during periods of 0-100 h, as a function of the nature of the polysaccharides, to produce either (i) monolithic or (ii) powder forms.
d) Stage 4: Solvent exchange (more details in [0022]).
e) Stage 5: Drying.
f) Stage 6: Thermal carbonisation of the obtained mesoporous polysaccharides.

According to the present invention, in order to provide the most cost and energy efficient method for production of the final carbonaceous nanocomposite material, a novel method of treatment of the materials obtained after stage 3 (retrogradation) have been developed. This novel method of solvent exchange and drying is based on the discovery that native polysaccharides can be stabilised in the form of an organic gel (a gel is a type of colloid in which solid particles are suspended and meshed in a liquid such that a rigid or semi-rigid mixture results) with aromatic hydrocarbons and some polar solvents. Starting from the aqueous polysaccharide gel, the method consists of the following steps:
a) Step 1: Addition to an aqueous polysaccharide gel of a polar solvent (A) that has a high boiling point and is miscible in both water and hydrocarbons produces a polysaccharide-water-A gel.
b) Step 2: Distillation under vacuum at 40° C. to completely remove water produces a polysaccharide-A gel.
c) Step 3: As a function of the nature of the polysaccharide, pH adjustment is undertaken with an adequate solvent.
d) Step 4: A number of solvent exchanges between polysaccharide-A-gel with an organic aromatic hydrocarbon solvent (B) to produce polysaccharide-B gel separately from an A/B mixture.
e) Step 5: Distillation of A/B solvent mixture to recover A and B
f) Step 6: Carbonization of polysaccharide-B gel to produce mesoporous carbonaceous precursor material and recover solvent B (with or without the presence of an acid catalyst as a function of polysaccharide)
g) Step 7: Carbonization of obtained carbonaceous precursor at target temperature (150-1300° C.)

Examples of solvent A could include but not limited to sulfolane, and others. Examples of solvent B could include but not limited to toluene, xylene, chlorobenzene, cyrene and others. Using this method full solvent recovery is achieved, or reduction of the amount of solvent used in the processes employed to maintain the initial mesoporous structure before and during part of the carbonisation process,

The invention allows the preparation of monolithic or powdered materials, defined at stage 3 described in [0021] by the use, or not, of a mould. This mould can take numerous forms, allowing the development of shaped mesoporous materials with good mechanical and dimensional stability.

One key aspect of the invention is the dispersion of the nanoparticles. Particularly preliminary dispersion strategies such as, ball-milling and/or sonication etc. to optimise the solution dispersions prior to gelation, and a solubilisation effect of the nanoparticles within the molten polysaccharide during thermal treatment, leading to highly dispersed nanoparticles in intimate contact with the polymer.

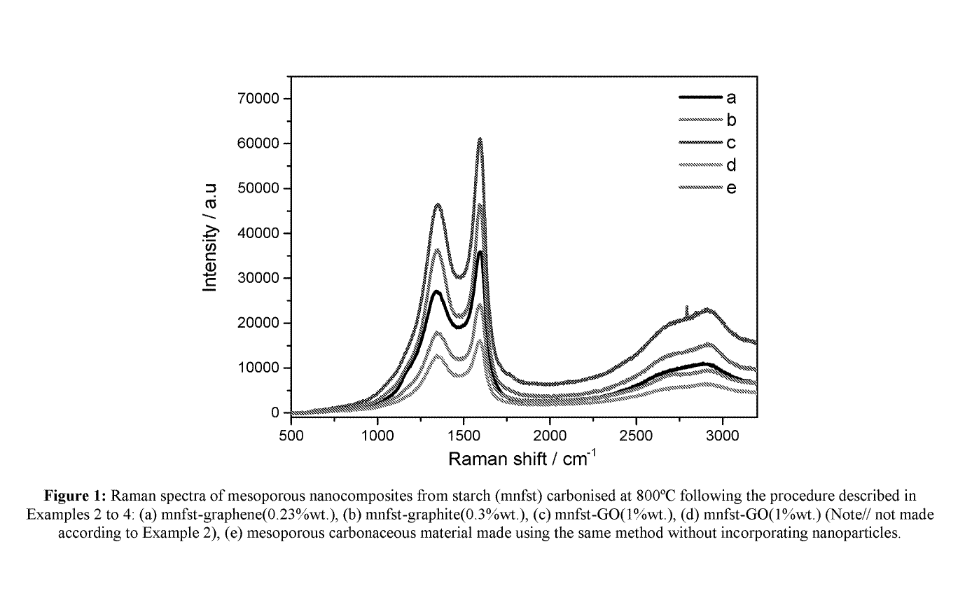

Raman spectroscopy is a well-known technique for interrogating the structural details of carbon materials [10]. Raman analysis of the materials produced spectra, with characteristic band positions and bandwidths indicating that the integrity of the material is maintained throughout the process, as can be seen in FIG. 1 for a series of materials produced.

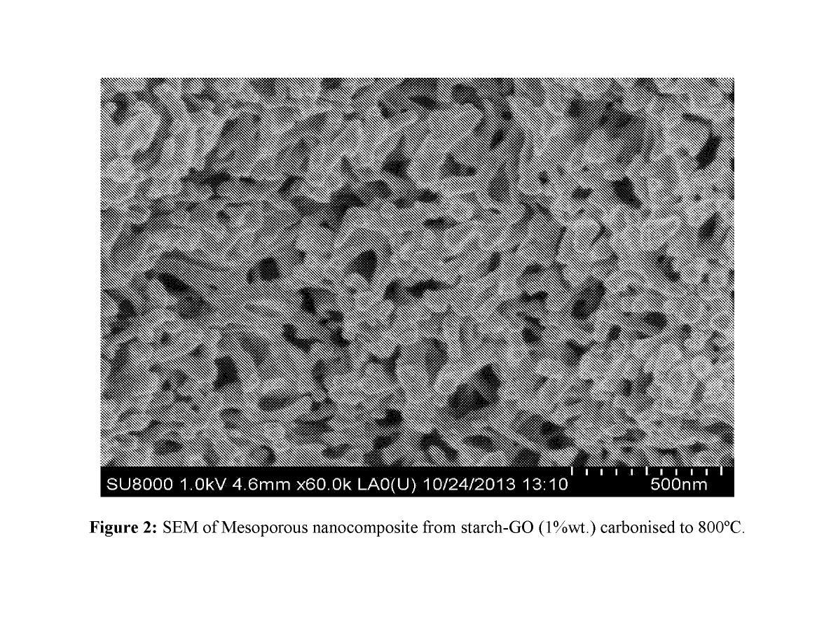

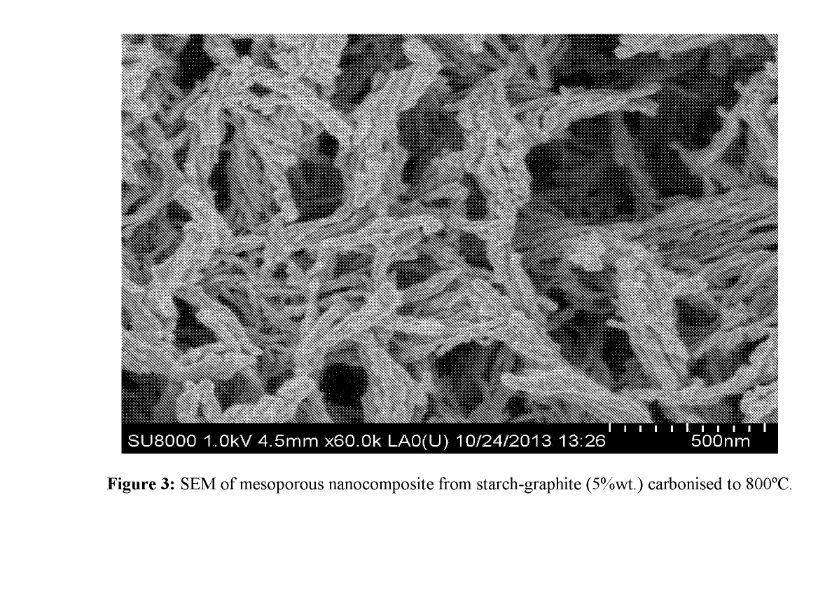

Another key aspect of the invention is the role of mesoporosity, and the synergetic effect of the nanoparticles within the mesoporous system. On the one hand, the location of the nanoparticles in the system is driven by the formation of the mesoporous structure, which incorporates the nanoparticles into the pore walls. On the other hand, the nanoparticle type and concentration has an important influence both on the mesopore and macropore size, pore shape, geometry, tribology, hardness, mechanical properties and density. This synergetic effect is tuneable and can be controlled by the processing temperature over the whole temperature range (150 -1300° C.), and could play an important role in applications such as adsorption, chromatography, catalysis, solar thermal collectors and electrochemistry etc. An illustration of this can be found by comparing scanning electron microscopy (SEM) images in FIGS. 2 and 3. This is because the surface energy of the pore is affected by the nanoparticle, which is reflected in the density of the mesoporous nanocomposite materials (see values given in examples).

In relation to the previous statement, another key aspect of the invention is the tuning of the mesoporosity at a given processing temperature by incorporating specific functionalisation via the carbon nanoparticles. Functionalised nanoparticles can be obtained commercially, and a range of different chemical groups can be found, including carboxyl, amine, epoxide, etc. The incorporation of new functional groups via the nanoparticles is fundamentally applicable in high mesoporosity systems, since in materials with high macropore content the surface area is relatively small, so any change in the chemical properties through functionalisation of the nanoparticle will have little impact. At the other extreme, if the micropore content is high, the physical energy in the pore will be so high that it can overcome any possible change in surface energy induced by chemical functionality. However, the mesoporous structure allows tuneability, since the nanoparticles are located in the pore walls. Incorporating different functional groups can radically change the surface energy of the nanoparticles. This will have a high impact on the macroscopic properties (monoliths) and provides a route to tailored in-pore reactivity.

The incorporation of CNT and graphene derivatives (GO, rGO, f-G, etc.) at intermediate stages of mesoporous polysaccharides carbonisation is also proposed with the following specific aims; to provide mechanical reinforcement to the mesoporous carbonaceous materials, to improve thermal and electrical properties, to introduce specific functionality at the polysaccharide-nanoparticle interface that may lead to the design of nanoparticle-mediated tailoring of chemical selectivity in the mesoporous structure, to permit the optimisation of the formation of shaped monolithic mesoporous materials through innovative in-situ cure strategies with polymeric and non-polymeric binders, to prepare gradient and/or multilayer systems with alternating or gradient reactivity, conductivity, etc., and to simplify solvent exchanging/drying steps.

The invention will now be described by way of example only and with reference to the accompanying figures in which:

FIG. 1 illustrates Raman spectra of mesoporous nanocomposites from starch (mnfst) carbonised at 800° C. following the procedure described in Examples 2 to 4: (a) mnfst-graphene (0.23% wt.), (b) mnfst-graphite(0.3% wt.), (c) mnfst-GO(1% wt.), (d) mnfst-GO(1% wt.) (Note//not made according to Example 2), (e) mesoporous carbonaceous material made using the same method without incorporating nanoparticles.

FIG. 2 is an SEM of a mesoporous nanocomposite from starch-GO (1% wt.) carbonised to 800° C.;

FIG. 3 is an SEM of a mesoporous nanocomposite from starch-graphite (5% wt.) carbonised to 800° C.;

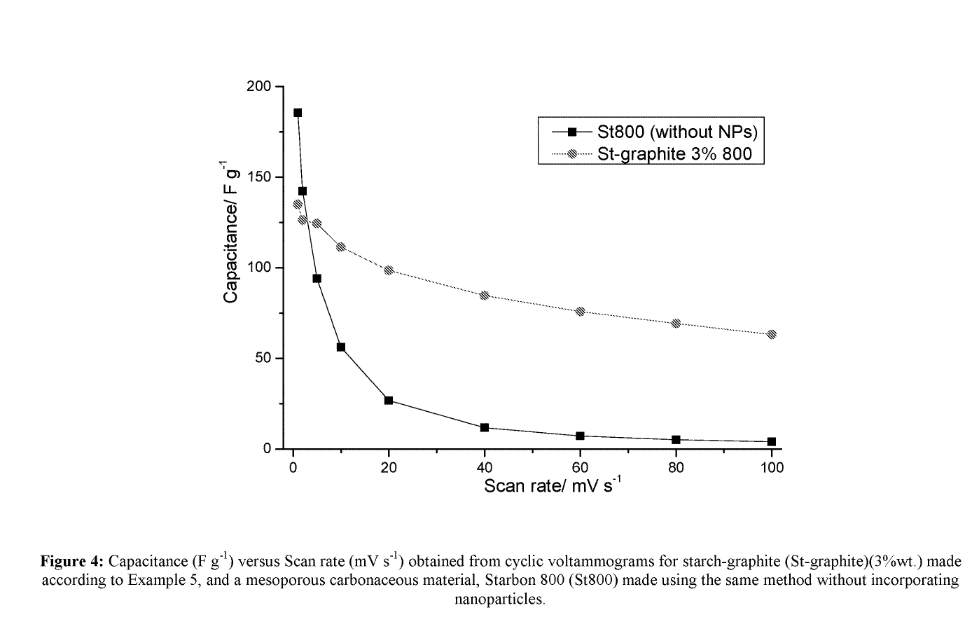

FIG. 4 is a plot of Capacitance (F g⁻¹) versus Scan rate (mV s⁻¹) obtained from cyclic voltammograms for St-graphite(3% wt.) made according to Example 5, and a mesoporous carbonaceous material made using the same method without incorporating nanoparticles.

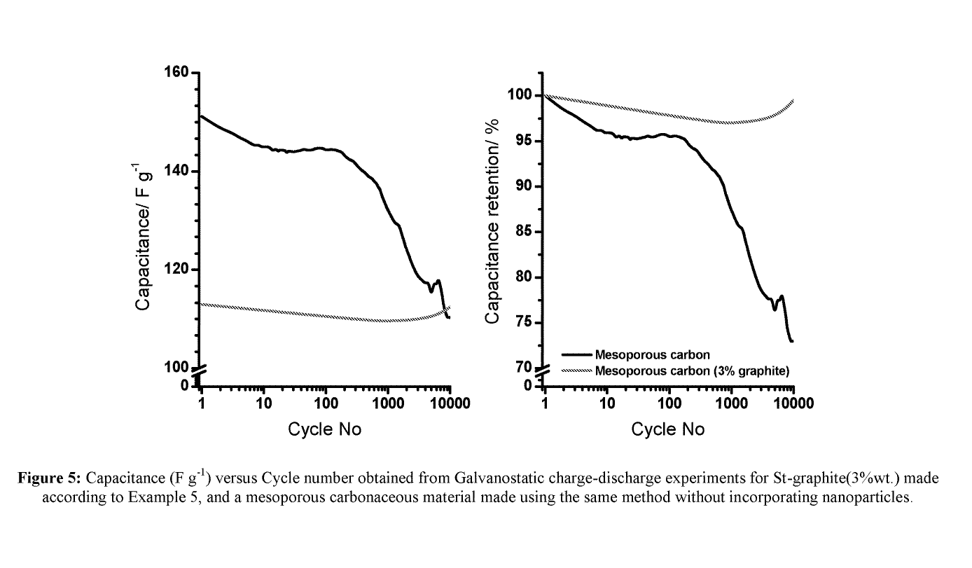

FIG. 5 is a plot of Capacitance (F g⁻¹) versus Cycle number obtained from Galvanostatic charge-discharge experiments for starch graphite (St-graphite) (3% wt.) made according to Example 5, and a mesoporous carbonaceous material, Starbon 800 (St800) made using the same method without incorporating nanoparticles.

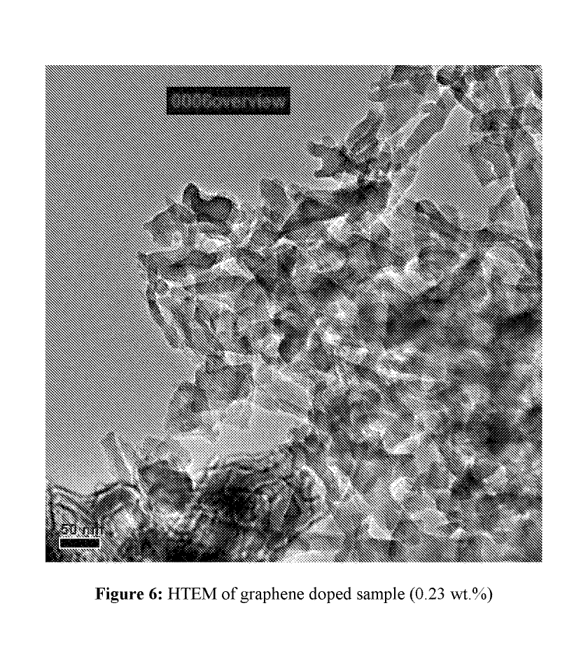

FIG. 6 is an HTEM of graphene doped sample (0.23 wt. %)

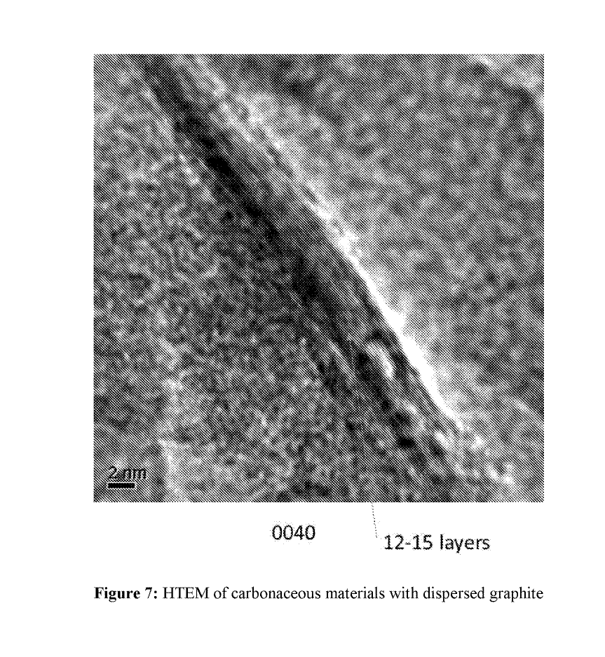

FIG. 7 is an HTEM of carbonaceous materials with dispersed graphite

### RESULTS AND EXAMPLES

### Example 1

### Solvent Exchange Method

Incorporating sulfolane to a starch aqueous gel produces a starch- water-sulfolane gel. Distillation at 40° C. under vacuum produces a starch-sulfolane gel. Incorporating toluene produces a starch-toluene gel. Addition of p-toluenesulfonic acid (TsOH) and subsequent carbonisation produces a mesoporous carbonaceous material, and a sulfolane-toluene mixture. On carbonisation of the starch-toluene gel, toluene is recovered, and on distillation of the sulfolane-toluene mixture, both solvents are also fully recovered.

### Example 2

### Monolithic Mesoporous Materials

A method for preparation of monolithic mesoporous materials from polysaccharide precursors and carbon based nanoparticles, and chemically functionalised carbon based nanoparticles. In this case a mixture of graphene oxide (1 wt. %) with starch was employed using the method detailed in paragraphs [0021] and [0022]. The starch-GO mixture (5 g) and 25 ml 4of water was added to a 35 ml microwave vial. And the following experimental procedure employed: The contents of the vial were heated in a CEM discover laboratory microwave at 140° C. for 1 minute. TsOH was then added to the contents and the mixture was sonicated for 3 minutes and then poured into moulds that were maintained at 5° C. for 24 hours. Subsequently, the shaped solid gel was placed in a vacuum tube and sulfolane was added in sufficient quantity to cover the material. The tube was then placed under vacuum and heated from 20 to 80° C. in 10° C. increments over a period of 10 hours. The sulfolane was then removed and toluene added, it was heated at 70° C. for 1 hour and held at 50° C. for 12 hours. The toluene was then removed and the sample placed in a vacuum oven at 70° C. for 24 hours. The sample was then carbonised by heating under vacuum according to the following program: 1° C./min to 120° C., 0.2° C./min to 180° C., hold for 4 hours, 0.2° C./min to 300° C., hold for 3 hours, 0.3° C./min to 400° C., 1° C./min to 800° C.

The material obtained as a monolith had a total pore volume higher than 0.4 ml/g with degree of mesoporosity higher than 85%, a density of 0.5 gcm⁻³ and a conductivity of 660 Sm⁻¹. The morphology of this material can be observed in the SEM image of FIG. 2, and characteristic bands are observed in the Raman spectrum in FIG. 1c.

### Example 3

### Monolithic Mesoporous Materials

Material was prepared as Example 2, but with a graphene content of 0.23 wt. %. The starch-rGO mixture (5 g) and 25 ml of water was added to a 35 ml microwave vial. The subsequent experimental procedure employed was as in Example 2.

The material obtained as a monolith has total pore volume higher than 0.4 ml/g with degree of mesoporosity higher than 85%, a density of 0.22 gcm⁻³ and a conductivity of 366 Sm⁻¹. Characteristic bands are observed in the Raman spectrum in FIG. 1a.

### Example 4

### Monolithic Mesoporous Materials

Material was prepared as Example 2, but with a graphite content of 0.3 wt. %. Starch and graphite were premixed and ball-milled for 1 hour at 500 rpm. The starch-graphite mixture (5 g) and 25 ml of water was added to a 35 ml microwave vial. The subsequent experimental procedure employed was as in example 2.

The material obtained as a monolith has total pore volume higher than 0.4 ml/g with degree of mesoporosity higher than 85%, a density of 0.25 gcm⁻³ and a conductivity of 255 m⁻¹. Characteristic bands are observed the Raman spectra in FIG. 1b.

### Example 5

### Monolithic Mesoporous Materials

Material was prepared as Example 2, with a graphite content of 3 wt. %. Starch and graphite were premixed and ball-milled for 30 minutes at 500 rpm. The starch-graphite mixture (5 g) and 25 ml of water was added to a 35 ml microwave vial. The subsequent experimental procedure employed was as in example 2.

The material obtained as a monolith has total pore volume higher than 0.4 ml/g with degree of mesoporosity higher than 85% and a capacitance greater than 125 Fg⁻¹ (cyclic voltammetry) (see FIG. 4) at a scan rate of 2 mV using 2.0 M H₂SO₄ solution as the electrolyte and greater than 99% capacitance retention after 10000 cycles (galvanostatic charge/discharge experiments) (see FIG. 5).

### Example 6

### Monolithic Mesoporous Materials

Material was prepared as Example 2, with a graphite content of 5 wt. %. Starch and graphite were premixed and ball-milled for 1 hour at 500 rpm. The starch-graphite mixture (5 g) and 25 ml of water was added to a 35 ml microwave vial. The subsequent experimental procedure employed was as in example 2.

The material obtained as a monolith has total pore volume higher than 0.4 ml/g with degree of mesoporosity higher than 85%, a density of 0.15 gcm⁻³ and a conductivity of 461 Sm⁻¹. The morphology of this material can be observed in the SEM image of FIG. 3.

### Example 7

### Textural Properties of the Proposed Materials

Information about textural properties of some of the examples of obtained mesoporous carbonaceous composite materials derived from native polysaccharides incorporating carbon-based nanoparticles is shown in Table 1.

TABLE 1

| | | | | Average |
|---|---|---|---|---|
| Carbon-based | Loading | S_{BET} | V | Pore diameter |
| nanoparticle | (%) | (m²g⁻¹) | (cm³g⁻¹) | (nm) |
| Graphene oxide | 1 | 241 | 1.22 | 9.3 |
| Graphene | 0.23 | 390.7 | 1.44 | 7.7 |
| Graphite | 5 | 448 | 0.52 | 5.3 |
| Graphite | 0.3 | 251.9 | 1.05 | 8.9 |

### Example 8

### High-Resolution Transmission Electron Microscopy

Information about distribution of carbon nanoparticles within carbonaceous matrix for some of the examples is shown in FIGS. 6 and 7 herein.

### Competitors

1. Mesoporous carbon composite containing carbon nanotube; EP 1686106 B 1

### REFERENCES

### Patent References

P1 Worldwide Patent WO2007104798 A3, Nov. 1 2007 “Mesoporous carbonaceous materials, preparation and use thereof”
P2 Worldwide Patent WO2004041915 A1 “Method to produce graphite/polymer composites”
P3 Chinese Patent CN 103342348 A, Jun. 14 2013 “Preparation method for graphene/carbon microsphere composite”
P4 Chinese Patent CN102544459A, Jan. 12 2012 “Method for preparing graphene-coated carbon microsphere material by coating graphene oxide on carbon microsphere”
P5 European Patent EP 0109839 B1, Sep. 6 1989 “Method of making graphite electrodes”

### Non-Patent References

1 Knox J H, Ross P: Carbon-based packing materials for liquid chromatography-structure, performance, and retention mechanisms. Advances in Chromatography, Vol 37 1997; 37:73-119.
2 Kruk M, Jaroniec M, Ryoo R, Joo S H: Characterization of ordered mesoporous carbons synthesized using mcm-48 silicas as templates. Journal of Physical Chemistry B 2000; 104:7960-7968.
3 Hu Z H, Srinivasan M P, Ni Y M: Novel activation process for preparing highly microporous and mesoporous activated carbons. Carbon 2001; 39:877-886.
4 Zhang F Q, Meng Y, Gu D, Yan Y, Yu C Z, Tu B, Zhao D Y: A facile aqueous route to synthesize highly ordered mesoporous polymers and carbon frameworks with ia(3)over-bard bicontinuous cubic structure. Journal of the American Chemical Society 2005; 127:13508-13509.
5 Karimi B, Biglari A, Clark J H, Budarin V: Green, Transition-Metal-Free Aerobic Oxidation of Alcohols Using a Highly Durable Supported Organocatalyst. Angewandte Chemie International Edition, 46, 7210-7213 (2007) DOI: 10.1002/anie.200701918
6 Novoselov, K. S.; Geim, A. K.; Morozov, S. V.; Jiang, D.; Zhang, Y.; Dubonos, S. V.; Grigorieva, I. V.; Firsov, A. A. “Electric Field Effect in Atomically Thin Carbon Films”, Science 306 (5696): 666-669 (2004). doi:10.1126/science.1102896
7 Salavagione, Horacio J; Martinez Gerardo, Ellis, Gary, Graphene-Based Polymer Nanocomposites, in Physics and Applications of Graphene -Experiments (Ed: Mikhailov, Sergey), InTech Publishing, Rijeka, Croacia Vol. 1, Cap. 9, p.169-192 (2011) ISBN: 978-953-307-217-3
8 Ŝupová, M; Martynková, Gra\hat{z}yna S; Barabaszová, K. “Effect of Nanofillers Dispersion in Polymer Matrices: A Review”, Sci. Advanced Mater., 3 (1), 1-25 (2011) doi: 10.1166/sam.2011.1136
9 “Polysaccharide Nanocomposites Reinforced with Graphene Oxide and Keratin-Grafted Graphene Oxide”, Ind. Eng. Chem. Res., 51, 3619-3629 (2012) dx.doi.org/10.1021/ie200742x
10 a) “Raman Spectrum of Graphene and Graphene Layers”, Phys. Rev. Lett. 97, 187401 (2006) dx.doi.org/10.1103/PhysRevLett.97.187401.
10 b) Yan Wang, Daniel C. Alsmeyer, and Richard L. McCreery, Chem. Mater, 1990, 2, 557-563 “Raman Spectroscopy of Carbon Materials: Structural Basis of Observed Spectra”

1. A mesoporous composite material comprising carbon nanoparticles dispersed in a mesoporous carbonaceous material.

2. A mesoporous composite material according to claim 1 wherein the carbon nanoparticles are substantially homogenously dispersed in the mesoporous carbonaceous material.

3. A mesoporous composite material according to claim 1 or 2 wherein the carbon nanoparticles are based on one or more of graphene, graphene oxide, graphite and carbon nanotubes.

4. A mesoporous composite material according to claim 3 wherein the carbon nanoparticles are based on graphene or graphene oxide.

5. A mesoporous composite material according to any one of the preceding claims wherein the carbon nanoparticles are based on graphite.

6. A mesoporous composite material according to any one of claims 1 to 4 wherein the carbon nanoparticles are based on carbon nanotubes.

7. A mesoporous composite material according to any one of the preceding claims wherein the mesoporous carbonaceous material is derived from one or more mesoporous polysaccharides.

8. A mesoporous composite material according to claim 7 wherein the mesoporous carbonaceous material is produced by the carbonisation of one or more mesoporous polysaccharides.

9. A mesoporous composite material according to any one of the preceding claims wherein the mesoporous composite material precursor is in the form of a stable organic gel before the carbonisation step.

10. A mesoporous composite material according to any one of the preceding claims wherein the C:O ratio is tuneable.

11. A mesoporous composite material according to any one of the preceding claims wherein the composite material is shaped in different forms.

12. A mesoporous composite material according to claim 11 wherein the composite material is a monolith with a tuneable micro-/mesopore structure throughout.

13. A mesoporous composite material according to any one of the preceding claims wherein the material has a tailored pore distribution.

14. A mesoporous composite material according to any one of the preceding claims wherein the material has improved electrical conductivity.

15. A mesoporous composite material according to any one of the preceding claims wherein the material has improved thermal conductivity.

16. A mesoporous composite material according to any one of the preceding claims wherein the material has improved absorption in the electromagnetic spectrum.

17. A mesoporous composite material according to any one of the preceding claims wherein the material incorporates extra functionality via specific functionalisation on the nanoparticle surface.

18. A mesoporous composite material according to any one of claims 1 to 15 wherein the material incorporates extra functionality via temperature mediated carbonisation of the polysaccharide or the polysaccharide/nanoparticle hybrid.

19. A mesoporous composite material according to any one of the preceding claims wherein the material has controllable macroporosity (density).

20. A method of preparing a mesoporous composite material comprising carbon nanoparticles dispersed in a mesoporous carbonaceous material according to claim 1, said method comprising:
dispersion of the carbon nanoparticles in a molten carbonaceous material.

21. A method of preparing a mesoporous composite material according to claim 19 wherein the mesoporous carbonaceous material is prepared by solvent exchange and drying of the carbonaceous material.

22. A mesoporous composite material, method, as herein described with reference to the accompanying description, examples and figures.
